(19) United States
(12) Patent Application Publication
(10) Pub. No.: US 2012/0162089 A1
(43) Pub. Date: Jun. 28, 2012

(54) TOUCH SCREEN TRANSISTOR DOPING PROFILES

(76) Inventor: Shih Chang CHANG, San Jose, CA (US)

(21) Appl. No.: 12/976,778

(22) Filed: Dec. 22, 2010

(51) Int. Cl. G06F 3/041; H01L 33/08

(52) U.S. Cl. 345/173; 438/37; 257/E33.005

(57) ABSTRACT

Variations in capacitances of semiconductor circuit elements, such as pixel TFTs, of touch screens can be reduced or eliminated by selectively doping different regions of the semiconductor circuit element. For example, the semiconductor circuit element can include a semiconductive channel of a transistor, such as a pixel TFT. A dopant concentration profile of the semiconductive channel can be selected to reduce or eliminate variations in a gate-to-drain capacitance caused by voltage variations at the drain.

### FIELD OF THE DISCLOSURE

This relates generally to touch sensing, and more particularly, to doping profiles of transistors in touch screens.

### BACKGROUND OF THE DISCLOSURE

Many types of input devices are presently available for performing operations in a computing system, such as buttons or keys, mice, trackballs, joysticks, touch sensor panels, touch screens and the like. Touch screens, in particular, are becoming increasingly popular because of their ease and versatility of operation as well as their declining price. Touch screens can include a touch sensor panel, which can be a clear panel with a touch-sensitive surface, and a display device such as a liquid crystal display (LCD) that can be positioned partially or fully behind the panel so that the touch-sensitive surface can cover at least a portion of the viewable area of the display device. Touch screens can allow a user to perform various functions by touching the touch sensor panel using a finger, stylus or other object at a location often dictated by a user interface (UI) being displayed by the display device. In general, touch screens can recognize a touch and the position of the touch on the touch sensor panel, and the computing system can then interpret the touch in accordance with the display appearing at the time of the touch, and thereafter can perform one or more actions based on the touch. In the case of some touch sensing systems, a physical touch on the display is not needed to detect a touch. For example, in some capacitive-type touch sensing systems, fringing electrical fields used to detect touch can extend beyond the surface of the display, and objects approaching near the surface may be detected near the surface without actually touching the surface.

Capacitive touch sensor panels can be formed from a matrix of drive and sense lines of a substantially transparent conductive material, such as Indium Tin Oxide (ITO), often arranged in rows and columns in horizontal and vertical directions on a substantially transparent substrate. It is due in part to their substantial transparency that capacitive touch sensor panels can be overlaid on a display to form a touch screen, as described above. Some touch screens can be formed by integrating touch sensing circuitry into a display pixel stackup (i.e., the stacked material layers forming the display pixels).

### SUMMARY

In some touch screens, variations in pixel voltages can cause errors due to variations in capacitances of semiconductor circuit elements within the touch screen. For example, a gate-to-drain capacitance of a pixel TFT can vary depending on the pixel voltage of the connected pixel electrode. In some systems, the variations in gate-to-drain capacitance in the pixel TFTs can introduce error in the touch system through an error mechanism, or error path, that can include, for example, a gate line of the display system. The following description includes examples of reducing or eliminating variations in capacitances of semiconductor circuit elements, such as pixel TFTs, of a touch screen by selectively doping different regions of the semiconductor circuit element. In some embodiments, the semiconductor circuit element can include a semiconductive channel of a transistor, such as a pixel TFT. A dopant concentration profile of the semiconductive channel can be selected to reduce or eliminate variations in a gate-to-drain capacitance caused by voltage variations at the drain. In this way, for example, errors in touch sensing introduced through various error mechanisms can be reduced.

### BRIEF DESCRIPTION OF THE DRAWINGS

FIGS. 1A-1C illustrate an example mobile telephone, an example media player, and an example personal computer that each include an example touch screen according to embodiments of the disclosure.

FIG. 2 is a block diagram of an example computing system that illustrates one implementation of an example touch screen according to embodiments of the disclosure.

FIG. 3 is a more detailed view of the touch screen of FIG. 2 showing an example configuration of drive lines and sense lines according to embodiments of the disclosure.

FIG. 4 illustrates an example configuration in which touch sensing circuitry includes common electrodes (Vcom) according to embodiments of the disclosure.

FIG. 5 illustrates an exploded view of example display pixel stackups according to embodiments of the disclosure.

FIG. 6 illustrates an example touch sensing operation according to embodiments of the disclosure.

FIG. 7 illustrates a portion of an example touch screen during a touch sensing phase according to embodiments of the disclosure.

FIG. 8 illustrates a model of an example error mechanism in an example touch screen according to embodiments of the disclosure.

FIG. 9 illustrates a circuit diagram of a drive-sense operation of an example touch screen according to embodiments of the disclosure.

FIG. 10 illustrates a cross-section view of an example TFT structure according to embodiments of the disclosure.

FIG. 11 illustrates a cross-section view of another example TFT structure according to embodiments of the disclosure.

FIG. 12 illustrates a cross-section view of another example TFT structure according to embodiments of the disclosure.

FIG. 13 illustrates a cross-section view of another example TFT structure according to embodiments of the disclosure.

FIG. 14 illustrates a plan view of another example TFT structure according to embodiments of the disclosure.

FIG. 15 illustrates a plan view of another example TFT structure according to embodiments of the disclosure.

FIG. 16 illustrates a plan view of another example TFT structure according to embodiments of the disclosure.

FIG. 17 illustrates a plan view of another example TFT structure according to embodiments of the disclosure.

### DETAILED DESCRIPTION

In the following description of example embodiments, reference is made to the accompanying drawings which form a part hereof, and in which it is shown by way of illustration specific embodiments in which embodiments of the disclosure can be practiced. It is to be understood that other embodiments can be used and structural changes can be made without departing from the scope of the embodiments of this disclosure.

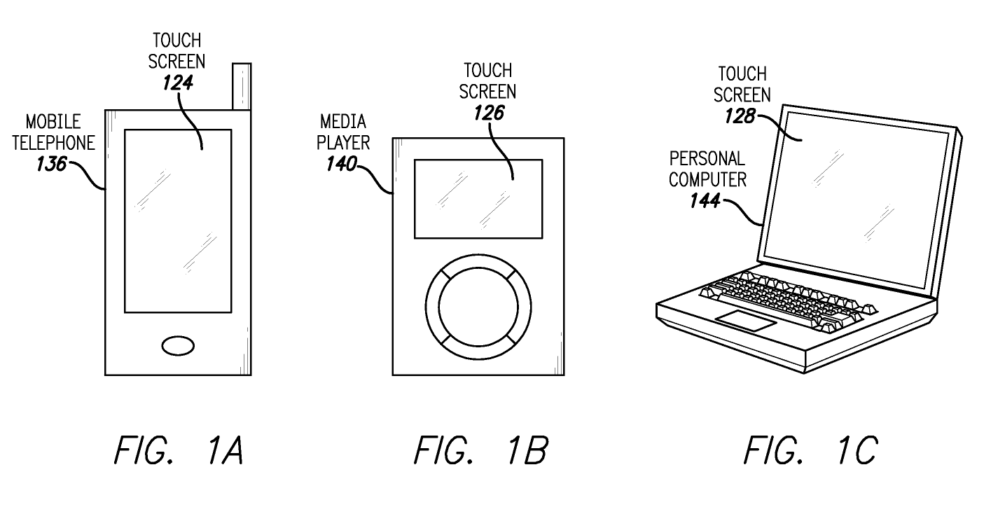

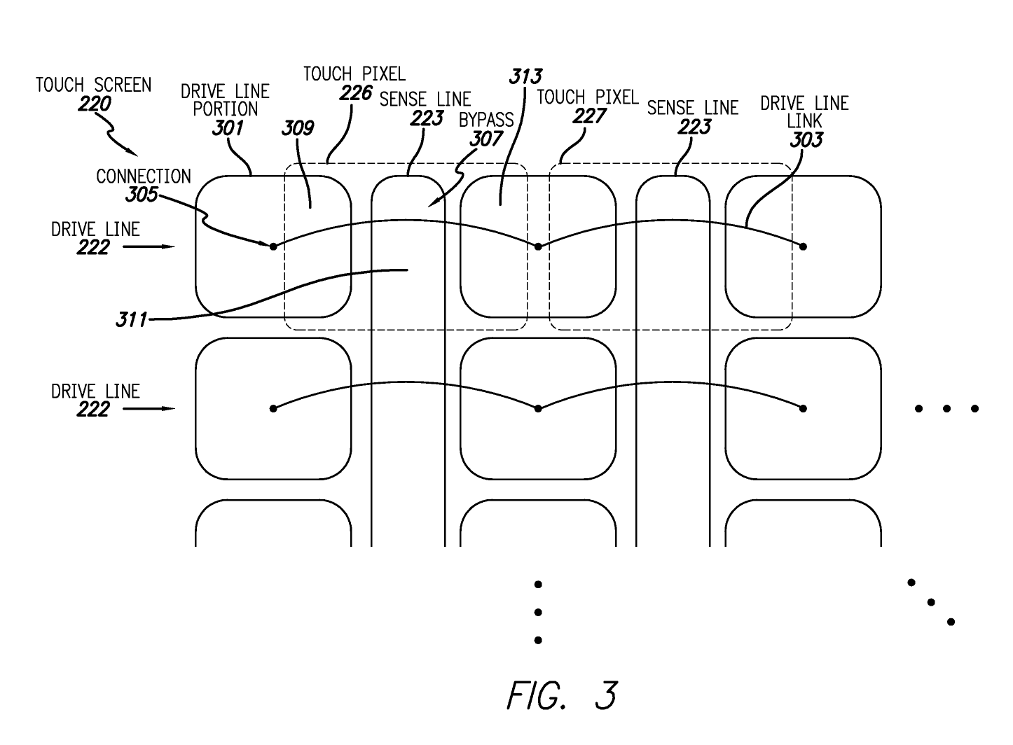

The following description includes examples in which transistors in the display systems of touch screens can include semiconductor channels with doping profiles that can help reduce or eliminate some errors that would otherwise be introduced into the touch sensing system. Various example systems that can include touch screens according to various embodiments, such as the systems illustrated in FIGS. 1A-C and 2, will be described. Next, example embodiments of integrated touch screens according to various embodiments will be described in relation to FIGS. 3-6. Next, example error mechanisms and example touch screen structures that can give rise to error mechanisms will be described in relation to FIGS. 7-9. Example touch screen structures including transistors with semiconductive channels having particular doping profiles that can help reduce or eliminate errors resulting from some error mechanisms will then be described in relation to FIGS. 10-17. First, a brief introduction will now be presented.

Touch sensing circuitry in devices such as touch panels, touch screens, etc., can be exposed to various sources of error that can enter the touch sensing system through various error mechanisms. For example, touch sensing circuitry can operate alongside other types of circuitry, such as in a touch screen formed by a touch panel overlay on a display screen. Close proximity of touch and display circuitry may cause undesirable interference, such as crosstalk, with touch sensing. Sources of error can enter the touch sensing system through various mechanisms. For example, a display system of a touch screen may apply voltages to pixel electrodes of the display pixels to display an image. The pixel voltages can vary among the pixel electrodes dependent on, for example, the various brightnesses and colors of the image being displayed. In some touch screens, the variations in pixel voltages can cause variations in capacitances of semiconductor circuit elements within the touch screen. For example, a gate-to-drain capacitance of a pixel TFT can vary depending on the pixel voltage of the connected pixel electrode, as described in more detail below. In some systems, the variations in gate-to-drain capacitance in the pixel TFTs can introduce error in the touch system through an error mechanism, or error path, that can include, for example, a gate line of the display system.

Errors in touch sensing can include any portion of a touch sensing measurement that does not carry information about touch. A touch sensing signal output from a touch sensor can be a composite signal, for example, that includes one or more signals caused by a touch, and carrying touch information about the touch, and one or more signals caused by other sources, such as electrical interference, crosstalk, etc., that do not provide information about the touch. Some error sources can cause a change in the operation of touch sensing that causes the portion of the touch sensing signal that carries touch information to inaccurately reflect the amount of touch. For example, an error source could cause a drive signal to be generated with an abnormally high voltage, which could result in the sense signal sensing a touch to be abnormally high as well. Thus, a portion of the touch information itself could include an error.

The following description includes examples of reducing or eliminating variations in capacitances of semiconductor circuit elements, such as pixel TFTs, of a touch screen by selectively doping different regions of the semiconductor circuit element. In some embodiments, the semiconductor circuit element can include a semiconductive channel of a transistor, such as a pixel TFT. A dopant concentration profile of the semiconductive channel can be selected to reduce or eliminate variations in a gate-to-drain capacitance caused by voltage variations at the drain. In this way, for example, errors in touch sensing introduced through various error mechanisms can be reduced.

Although example embodiments are described below in relation to integrated touch screens, other types of touch sensing arrangements can be used; for example, non-integrated touch screens, touchpads, etc.

FIGS. 1A-1C show example systems in which a touch screen according to embodiments of the disclosure may be implemented. FIG. 1A illustrates an example mobile telephone 136 that includes a touch screen 124. FIG. 1B illustrates an example digital media player 140 that includes a touch screen 126. FIG. 1C illustrates an example personal computer 144 that includes a touch screen 128. Touch screens 124, 126, and 128 may be based on, for example, self capacitance or mutual capacitance, or another touch sensing technology. For example, in a self capacitance based touch system, an individual electrode with a self-capacitance to ground can be used to form a touch pixel for detecting touch. As an object approaches the touch pixel, an additional capacitance to ground can be formed between the object and the touch pixel. The additional capacitance to ground can result in a net increase in the self-capacitance seen by the touch pixel. This increase in self-capacitance can be detected and measured by a touch sensing system to determine the positions of multiple objects when they touch the touch screen. A mutual capacitance based touch system can include, for example, drive regions and sense regions, such as drive lines and sense lines. For example, drive lines can be formed in rows while sense lines can be formed in columns (e.g., orthogonal). Touch pixels can be formed at the intersections of the rows and columns. During operation, the rows can be stimulated with an AC waveform and a mutual capacitance can be formed between the row and the column of the touch pixel. As an object approaches the touch pixel, some of the charge being coupled between the row and column of the touch pixel can instead be coupled onto the object. This reduction in charge coupling across the touch pixel can result in a net decrease in the mutual capacitance between the row and the column and a reduction in the AC waveform being coupled across the touch pixel. This reduction in the charge-coupled AC waveform can be detected and measured by the touch sensing system to determine the positions of multiple objects when they touch the touch screen. In some embodiments, a touch screen can be multi-touch, single touch, projection scan, full-imaging multi-touch, or any capacitive touch.

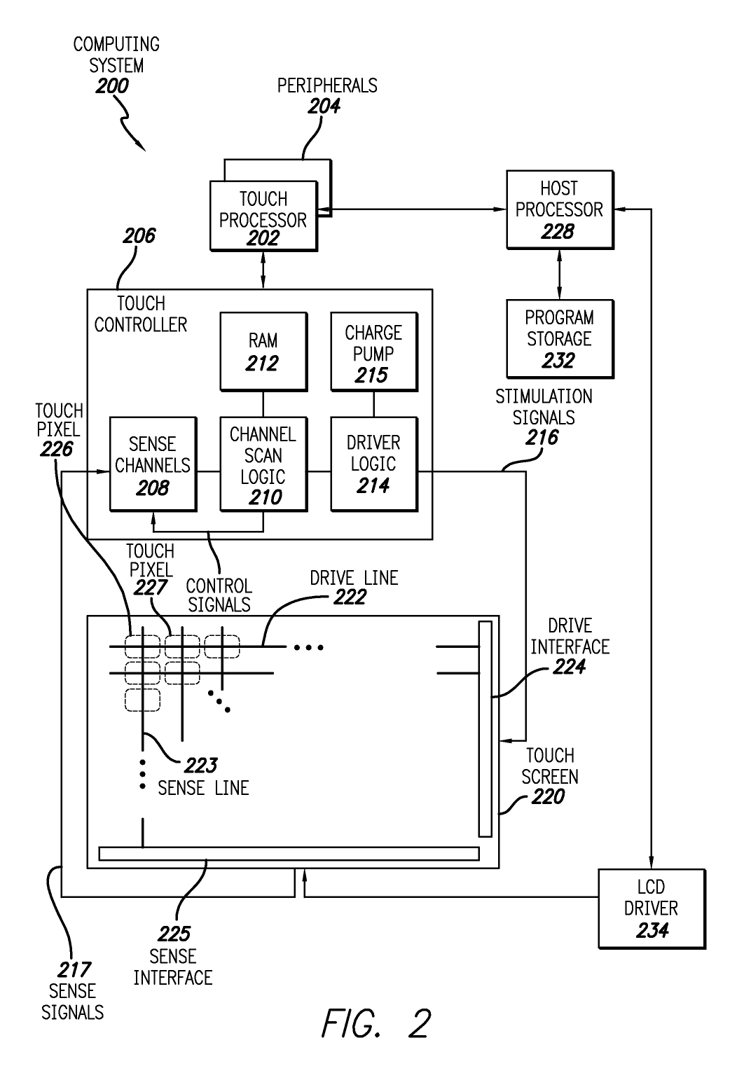

FIG. 2 is a block diagram of an example computing system 200 that illustrates one implementation of an example touch screen 220 according to embodiments of the disclosure. Computing system 200 could be included in, for example, mobile telephone 136, digital media player 140, personal computer 144, or any mobile or non-mobile computing device that includes a touch screen. Computing system 200 can include a touch sensing system including one or more touch processors 202, peripherals 204, a touch controller 206, and touch sensing circuitry (described in more detail below). Peripherals 204 can include, but are not limited to, random access memory (RAM) or other types of memory or storage, watchdog timers and the like. Touch controller 206 can include, but is not limited to, one or more sense channels 208, channel scan logic 210 and driver logic 214. Channel scan logic 210 can access RAM 212, autonomously read data from the sense channels and provide control for the sense channels. In addition, channel scan logic 210 can control driver logic 214 to generate stimulation signals 216 at various frequencies and phases that can be selectively applied to drive regions of the touch sensing circuitry of touch screen 220, as described in more detail below. In some embodiments, touch controller 206, touch processor 202 and peripherals 204 can be integrated into a single application specific integrated circuit (ASIC).

Computing system 200 can also include a host processor 228 for receiving outputs from touch processor 202 and performing actions based on the outputs. For example, host processor 228 can be connected to program storage 232 and a display controller, such as an LCD driver 234. Host processor 228 can use LCD driver 234 to generate an image on touch screen 220, such as an image of a user interface (UI), and can use touch processor 202 and touch controller 206 to detect a touch on or near touch screen 220, such a touch input to the displayed UI. The touch input can be used by computer programs stored in program storage 232 to perform actions that can include, but are not limited to, moving an object such as a cursor or pointer, scrolling or panning, adjusting control settings, opening a file or document, viewing a menu, making a selection, executing instructions, operating a peripheral device connected to the host device, answering a telephone call, placing a telephone call, terminating a telephone call, changing the volume or audio settings, storing information related to telephone communications such as addresses, frequently dialed numbers, received calls, missed calls, logging onto a computer or a computer network, permitting authorized individuals access to restricted areas of the computer or computer network, loading a user profile associated with a user's preferred arrangement of the computer desktop, permitting access to web content, launching a particular program, encrypting or decoding a message, and/or the like. Host processor 228 can also perform additional functions that may not be related to touch processing.

Touch screen 220 can include touch sensing circuitry that can include a capacitive sensing medium having a plurality of drive lines 222 and a plurality of sense lines 223. It should be noted that the term “lines” is a sometimes used herein to mean simply conductive pathways, as one skilled in the art will readily understand, and is not limited to elements that are strictly linear, but includes pathways that change direction, and includes pathways of different size, shape, materials, etc. Drive lines 222 can be driven by stimulation signals 216 from driver logic 214 through a drive interface 224, and resulting sense signals 217 generated in sense lines 223 can be transmitted through a sense interface 225 to sense channels 208 (also referred to as an event detection and demodulation circuit) in touch controller 206. In this way, drive lines and sense lines can be part of the touch sensing circuitry that can interact to form capacitive sensing nodes, which can be thought of as touch picture elements (touch pixels), such as touch pixels 226 and 227. This way of understanding can be particularly useful when touch screen 220 is viewed as capturing an “image” of touch. In other words, after touch controller 206 has determined whether a touch has been detected at each touch pixel in the touch screen, the pattern of touch pixels in the touch screen at which a touch occurred can be thought of as an “image” of touch (e.g. a pattern of fingers touching the touch screen).

In some example embodiments, touch screen 220 can be an integrated touch screen in which touch sensing circuit elements of the touch sensing system can be integrated into the display pixels stackups of a display. An example integrated touch screen in which embodiments of the disclosure can be implemented with now be described with reference to FIGS. 3-6. FIG. 3 is a more detailed view of touch screen 220 showing an example configuration of drive lines 222 and sense lines 223 according to embodiments of the disclosure. As shown in FIG. 3, each drive line 222 can be formed of one or more drive line segments 301 that can be electrically connected by drive line links 303 at connections 305. Drive line links 303 are not electrically connected to sense lines 223, rather, the drive line links can bypass the sense lines through bypasses 307. Drive lines 222 and sense lines 223 can interact capacitively to form touch pixels such as touch pixels 226 and 227. Drive lines 222 (i.e., drive line segments 301 and corresponding drive line links 303) and sense lines 223 can be formed of electrical circuit elements in touch screen 220. In the example configuration of FIG. 3, each of touch pixels 226 and 227 can include a portion of one drive line segment 301, a portion of a sense line 223, and a portion of another drive line segment 301. For example, touch pixel 226 can include a right-half portion 309 of a drive line segment on one side of a portion 311 of a sense line, and a left-half portion 313 of a drive line segment on the opposite side of portion 311 of the sense line.

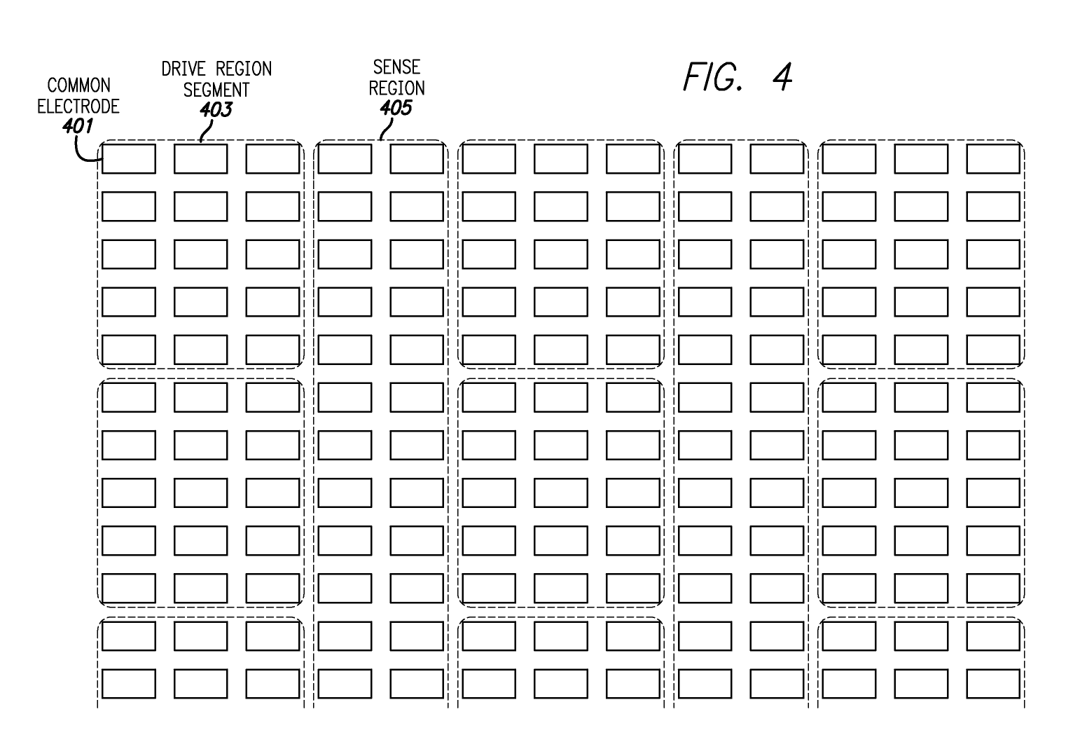

The circuit elements can include, for example, elements that can exist in conventional LCD displays, as described above. It is noted that circuit elements are not limited to whole circuit components, such a whole capacitor, a whole transistor, etc., but can include portions of circuitry, such as only one of the two plates of a parallel plate capacitor. FIG. 4 illustrates an example configuration in which common electrodes (Vcom) can form portions of the touch sensing circuitry of a touch sensing system. Each display pixel includes a common electrode 401, which is a circuit element of the display system circuitry in the pixel stackup (i.e., the stacked material layers forming the display pixels) of the display pixels of some types of conventional LCD displays, e.g., fringe field switching (FFS) displays, that can operate as part of the display system to display an image.

In the example shown in FIG. 4, each common electrode (Vcom) 401 can serve as a multi-function circuit element that can operate as display circuitry of the display system of touch screen 220 and can also operate as touch sensing circuitry of the touch sensing system. In this example, each common electrode 401 can operate as a common electrode of the display circuitry of the touch screen, and can also operate together when grouped with other common electrodes as touch sensing circuitry of the touch screen. For example, a group of common electrodes 401 can operate together as a part of a drive line or a sense line of the touch sensing circuitry during the touch sensing phase. Other circuit elements of touch screen 220 can form part of the touch sensing circuitry by, for example, electrically connecting together common electrodes 401 of a region, switching electrical connections, etc. In general, each of the touch sensing circuit elements may be either a multi-function circuit element that can form part of the touch sensing circuitry and can perform one or more other functions, such as forming part of the display circuitry, or may be a single-function circuit element that can operate as touch sensing circuitry only. Similarly, each of the display circuit elements may be either a multi-function circuit element that can operate as display circuitry and perform one or more other functions, such as operating as touch sensing circuitry, or may be a single-function circuit element that can operate as display circuitry only. Therefore, in some embodiments, some of the circuit elements in the display pixel stackups can be multi-function circuit elements and other circuit elements may be single-function circuit elements. In other embodiments, all of the circuit elements of the display pixel stackups may be single-function circuit elements.

In addition, although example embodiments herein may describe the display circuitry as operating during a display phase, and describe the touch sensing circuitry as operating during a touch sensing phase, it should be understood that a display phase and a touch sensing phase may be operated at the same time, e.g., partially or completely overlap, or the display phase and touch phase may operate at different times. Also, although example embodiments herein describe certain circuit elements as being multi-function and other circuit elements as being single-function, it should be understood that the circuit elements are not limited to the particular functionality in other embodiments. In other words, a circuit element that is described in one example embodiment herein as a single-function circuit element may be configured as a multi-function circuit element in other embodiments, and vice versa.

For example, FIG. 4 shows common electrodes 401 grouped together to form drive region segments 403 and sense regions 405 that generally correspond to drive line segments 301 and sense lines 223, respectively. Grouping multi-function circuit elements of display pixels into a region can mean operating the multi-function circuit elements of the display pixels together to perform a common function of the region. Grouping into functional regions may be accomplished through one or a combination of approaches, for example, the structural configuration of the system (e.g., physical breaks and bypasses, voltage line configurations), the operational configuration of the system (e.g., switching circuit elements on/off, changing voltage levels and/or signals on voltage lines), etc.

Multi-function circuit elements of display pixels of the touch screen can operate in both the display phase and the touch phase. For example, during a touch phase, common electrodes 401 can be grouped together to form touch signal lines, such as drive regions and sense regions. In some embodiments circuit elements can be grouped to form a continuous touch signal line of one type and a segmented touch signal line of another type. For example, FIG. 4 shows one example embodiment in which drive region segments 403 and sense regions 405 correspond to drive line segments 301 and sense lines 223 of touch screen 220. Other configurations are possible in other embodiments, for example, common electrodes 401 could be grouped together such that drive lines are each formed of a continuous drive region and sense lines are each formed of a plurality of sense region segments linked together through connections that bypass a drive region.

The drive regions in the example of FIG. 3 are shown in FIG. 4 as rectangular regions including a plurality of common electrodes of display pixels, and the sense regions of FIG. 3 are shown in FIG. 4 as rectangular regions including a plurality of common electrodes of display pixels extending the vertical length of the LCD. In some embodiments, a touch pixel of the configuration of FIG. 4 can include, for example, a 64×64 area of display pixels. However, the drive and sense regions are not limited to the shapes, orientations, and positions shown, but can include any suitable configurations according to embodiments of the disclosure. It is to be understood that the display pixels used to form the touch pixels are not limited to those described above, but can be any suitable size or shape to permit touch capabilities according to embodiments of the disclosure.

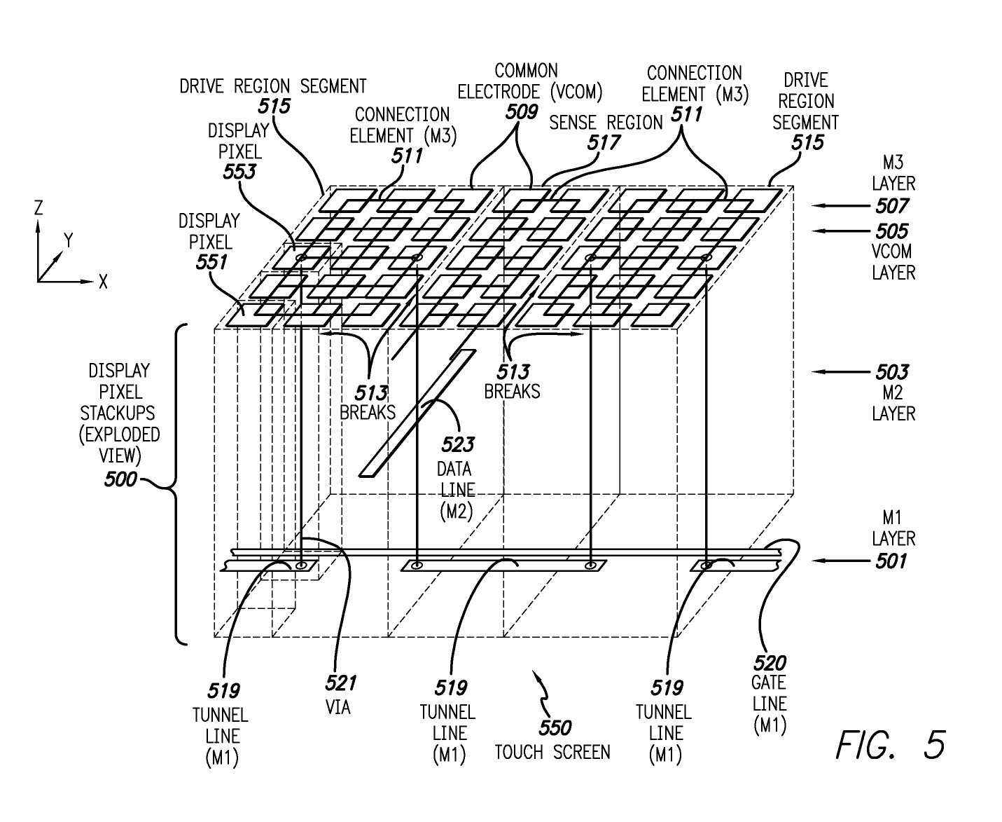

FIG. 5 is a three-dimensional illustration of an exploded view (expanded in the z-direction) of example display pixel stackups 500 showing some of the elements within the pixel stackups of an example integrated touch screen 550. Stackups 500 can include a configuration of conductive lines that can be used to group common electrodes, such as common electrodes 401, into drive region segments and sense regions, such as shown in FIG. 4, and to link drive region segments to form drive lines.

Stackups 500 can include elements in a first metal (M1) layer 501, a second metal (M2) layer 503, a common electrode (Vcom) layer 505, and a third metal (M3) layer 507. Each display pixel can include a common electrode 509, such as common electrodes 401 in FIG. 4, that is formed in Vcom layer 505. M3 layer 507 can include connection element 511 that can electrically connect together common electrodes 509. In some display pixels, breaks 513 can be included in connection element 511 to separate different groups of common electrodes 509 to form drive region segments 515 and a sense region 517, such as drive region segments 403 and sense region 405, respectively. Breaks 513 can include breaks in the x-direction that can separate drive region segments 515 from sense region 517, and breaks in the y-direction that can separate one drive region segment 515 from another drive region segment. M1 layer 501 can include tunnel lines 519 that can electrically connect together drive region segments 515 through connections, such as conductive vias 521, which can electrically connect tunnel line 519 to the grouped common electrodes in drive region segment display pixels. Tunnel line 519 can run through the display pixels in sense region 517 with no connections to the grouped common electrodes in the sense region, e.g., no vias 521 in the sense region. The M1 layer can also include gate lines 520. M2 layer 503 can include data lines 523. Only one gate line 520 and one data line 523 are shown for the sake of clarity; however, a touch screen can include a gate line running through each horizontal row of display pixels and multiple data lines running through each vertical row of display pixels, for example, one data line for each red, green, blue (RGB) color sub-pixel in each pixel in a vertical row of an RGB display integrated touch screen.

Structures such as connection elements 511, tunnel lines 519, and conductive vias 521 can operate as a touch sensing circuitry of a touch sensing system to detect touch during a touch sensing phase of the touch screen. Structures such as data lines 523, along with other pixel stackup elements such as transistors, pixel electrodes, common voltage lines, data lines, etc. (not shown), can operate as display circuitry of a display system to display an image on the touch screen during a display phase. Structures such as common electrodes 509 can operate as multifunction circuit elements that can operate as part of both the touch sensing system and the display system.

For example, in operation during a touch sensing phase, gate lines 520 can be clamped to a fixed voltage while stimulation signals can be transmitted through a row of drive region segments 515 connected by tunnel lines 519 and conductive vias 521 to form electric fields between the stimulated drive region segments and sense region 517 to create touch pixels, such as touch pixel 226 in FIG. 2. In this way, the row of connected together drive region segments 515 can operate as a drive line, such as drive line 222, and sense region 517 can operate as a sense line, such as sense line 223. When an object such as a finger approaches or touches a touch pixel, the object can affect the electric fields extending between the drive region segments 515 and the sense region 517, thereby reducing the amount of charge capacitively coupled to the sense region. This reduction in charge can be sensed by a sense channel of a touch sensing controller connected to the touch screen, such as touch controller 206 shown in FIG. 2, and stored in a memory along with similar information of other touch pixels to create an “image” of touch.

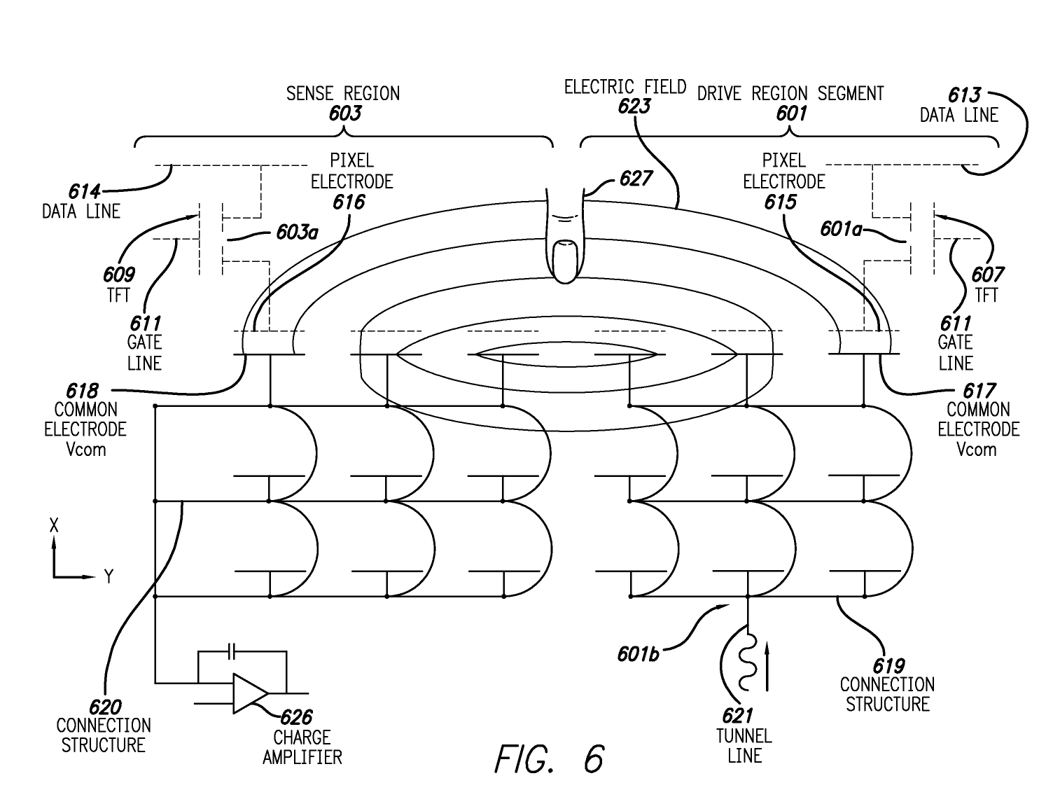

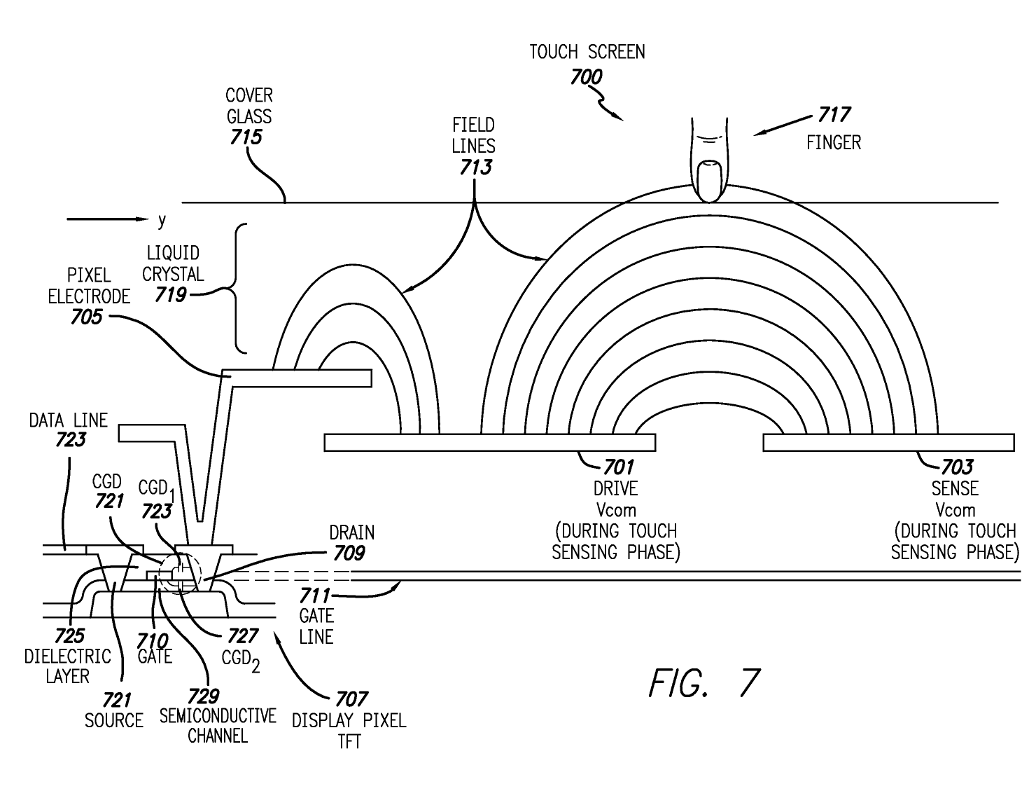

A touch sensing operation according to embodiments of the disclosure will be described with reference to FIG. 6. FIG. 6 shows partial circuit diagrams of some of the touch sensing circuitry within display pixels in a drive region segment 601 and a sense region 603 of an example touch screen according to embodiments of the disclosure. For the sake of clarity, only one drive region segment is shown. Also for the sake of clarity, FIG. 6 includes circuit elements illustrated with dashed lines to signify some circuit elements, such as pixel electrodes 615 and 616, can operate primarily as part of the display circuitry and not the touch sensing circuitry. In addition, a touch sensing operation is described primarily in terms of a single display pixel 601a of drive region segment 601 and a single display pixel 603a of sense region 603. However, it is understood that other display pixels in drive region segment 601 can include the same touch sensing circuitry as described below for display pixel 601a, and the other display pixels in sense region 603 can include the same touch sensing circuitry as described below for display pixel 603a. Thus, the description of the operation of display pixel 601a and display pixel 603a can be considered as a description of the operation of drive region segment 601 and sense region 603, respectively.

Referring to FIG. 6, drive region segment 601 includes a plurality of display pixels including display pixel 601a. Display pixel 601a can include a TFT 607, a gate line 611, a data line 613, a pixel electrode 615, and a common electrode 617. FIG. 6 shows common electrode 617 connected to the common electrodes in other display pixels in drive region segment 601 through a connection element 619 within the display pixels of drive region segment 601 that is used for touch sensing as described in more detail below. Sense region 603 includes a plurality of display pixels including display pixel 603a. Display pixel 603a includes a TFT 609, a data line 614, a pixel electrode 616, and a common electrode 618. TFT 609 can be connected to the same gate line 611 as TFT 607. FIG. 6 shows common electrode 618 connected to the common electrodes in other display pixels in sense region 603 through a connection element 620 that can be connected, for example, in a border region of the touch screen to form an element within the display pixels of sense region 603 that is used for touch sensing as described in more detail below.

During a display phase, a pixel voltage can be applied to pixel electrodes 615 and 616 through data lines 613 and 614, respectively. For example, a voltage applied to gate line 611 can turn on pixel TFTs 601a and 602a, such that a first voltage on data line 613 can be applied to pixel electrode 615, and a second voltage on data line 614 can be applied to pixel electrode 616. The first and second voltages can be different and dependent on the image to be displayed. During a touch sensing phase, gate line 611 can be connected to a fixed voltage source, such as a virtual ground in order to help reduce crosstalk, as described in more detail below. Drive signals can be applied to common electrodes 617 through a tunnel line 621 that is electrically connected to a portion of connection element 619 within a display pixel 601b of drive region segment 601. The drive signals, which are transmitted to all common electrodes 617 of the display pixels in drive region segment 601 through connection element 619, can generate an electrical field 623 between the common electrodes of the drive region segment and common electrodes 618 of sense region 603, which can be connected to a sense amplifier, such as a charge amplifier 626. Electrical charge can be injected into the structure of connected common electrodes of sense region 603, and charge amplifier 626 converts the injected charge into a voltage that can be measured. The amount of charge injected, and consequently the measured voltage, can depend on the proximity of a touch object, such as a finger 627, to the drive and sense regions. In this way, the measured voltage can provide an indication of touch on or near the touch screen.

FIG. 7 illustrates one example structure of a touch screen according to embodiments of the disclosure. FIG. 7 shows a touch screen 700 that can include a drive Vcom 701, a sense Vcom 703, and a pixel electrode 705. The pixel electrode 705 can be connected to a display pixel TFT 707 through a drain 709. Display pixel TFT 707 can include a gate 710 connected to a gate line 711, which can be a common gate line to the sense Vcom 703 (not shown in the figure). Drive Vcom can be driven by a drive signal, which can generate field lines 713. Some of field lines 713 can exit a cover glass 715 and reach finger 717. The field lines 713 that are affected by finger 717 can allow sense Vcom 703 to measure touch information.

Some of field lines 713 emitted from drive Vcom 701 can reach pixel electrode 705. Consequently, part of the drive signal that can be driving drive Vcom 701 can be picked up by pixel electrode 705, and this signal can be passed to gate line 711 through drain 709. In particular, there can be a capacitance between drain 709 and gate 710 that can allow a capacitive coupling of the portion of the drive signal captured by pixel electrode 705 into gate line 711. A gate-to-drain capacitance (CGD) 721 can include a combination of a capacitance (CGD1) 723 through a dielectric layer 725 of pixel TFT 707 and a capacitance (CGD2) 727 through a semiconductive channel 729 of the pixel TFT. The capacitance associated with a dielectric layer, such as dielectric layer 725, can be relatively independent of surrounding electrical fields. In this regard, the portion of the total gate-to-drain capacitance, CGD 721, that is associated with dielectric layer 725 can be relatively independent of an electric field between gate 710 and drain 709. In other words, CGD1 723 can remain relatively constant over a range of different pixel voltages that can be applied to pixel electrode 705 as different image frames are displayed on touch screen 700.

On the other hand, CGD2 727 represents the portion of the total gate-to-drain capacitance through a semiconductor, such as semiconductive channel 729. In some touch screens, CGD2 727 can be dependent on the pixel voltage of pixel electrode 705. In particular, a voltage difference between drain 709 (connected to pixel electrode 705) and gate 710 can create an electric field between drain 709 and gate 710. A portion of the electric field can extend through a region of semiconductive channel 729 and can induce carrier generation in the semiconductive channel. In other words, the electric field can generate electrons or holes in the region of the semiconductive channel, depending on the type of dopant of the semiconductor used in the region through which the electric field extends. The induced carrier generation can change the conductivity of the region of the semiconductive channel between gate 710 and drain 709, which can change the portion of the total the gate-to-drain capacitance associated with semiconductive channel 729, i.e., CGD2 727. The amount of induced carrier generation can depend on the strength of the electric field between drain 709 and gate 710, which in turn can depend on the pixel voltage applied to pixel electrode 705. Because the pixel voltage applied to pixel electrode 705 can vary over time as different image frames are displayed on touch screen 700, total gate-to-drain capacitance, CGD 721, can vary over time. In addition, because pixel voltages applied to different pixel electrodes of touch screen 700 can be different in each image frame, the total gate-to-drain capacitances of the sub-pixels of the touch screen can be different for any given image frame. Differences in gate-to-drain capacitances over time and/or sub-pixel location can cause errors, such as errors in touch sensing, as described in detail below.

During a display phase, a pixel voltage can be applied to a source 721 of pixel TFT 707 by a data line 723. Pixel TFT 707 can be switched to an on state by a voltage on gate line 711, such that the pixel voltage of source 721 can be applied to pixel electrode 705 through drain 709. Pixel TFT 707 can be switched to an off state, and pixel electrode 705 can be held at the pixel voltage to operate the pixel at the particular luminance required for that pixel in the current image. The pixel voltage can cause an electrical field between drain 709 and gate 710. In some touch screens, the electrical field through a portion of a semiconductor channel, such as semiconductor channel 729, can induce carrier generation in the semiconductor, thus changing the conductivity of the portion of the semiconductive channel between the drain and the gate. The changed conductivity corresponds to a changed dielectric constant of the portion of the semiconductive channel, thus changing the CGD2 value in some touch screens. Therefore, CGD can be dependent on pixel voltage in some touch screens. A variation in gate-to-drain capacitance among different display pixels can introduce an error in touch sensing, as described in more detail below.

Although FIG. 7 illustrates a single drive Vcom 701 and a single sense Vcom 703, in some embodiments these Vcoms can be connected together with Vcoms of a particular drive region and sense region such as the regions shown in FIGS. 4 and 5.

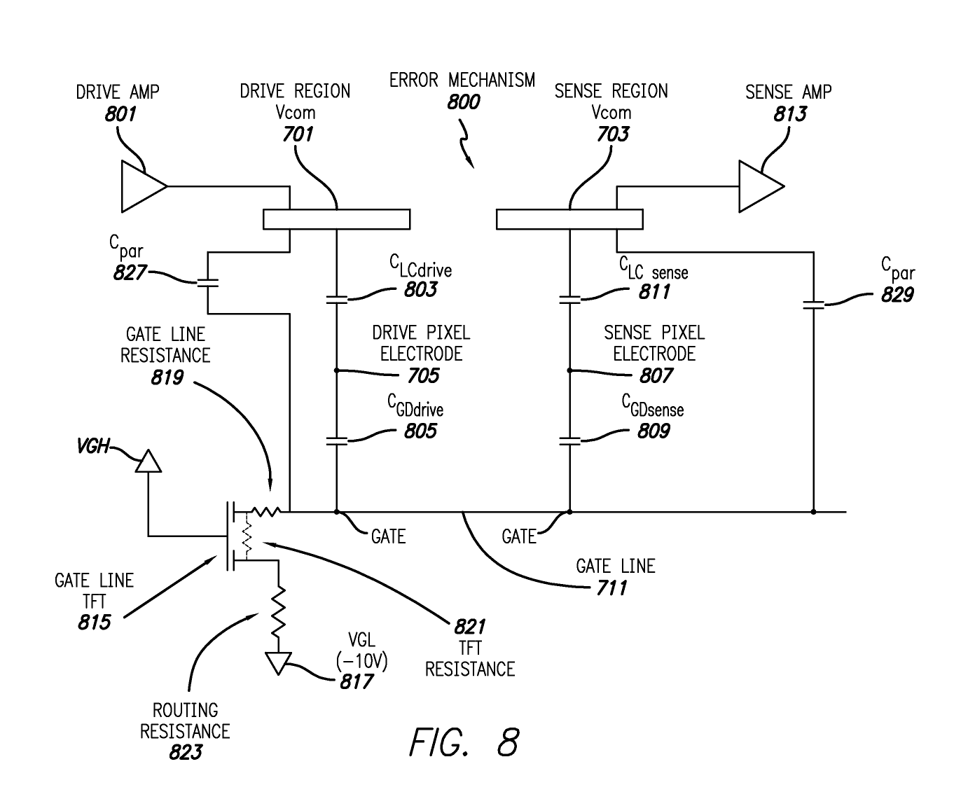

FIG. 8 illustrates an error mechanism 800 of the example portion of touch screen 700 in FIG. 7. A drive amplifier 801 can drive the drive region Vcom 701 with a drive signal as described above. A portion of the drive signal can be captured by pixel electrode 705 through field lines passing through liquid crystal 719. Liquid crystal 719 of display pixels in the drive region can have a capacitance, CLCdrive 803. Once captured by pixel electrode 705, the signal can be passed to gate line 711 through a capacitance between drain 709 and gate line 711, CGDdrive 805, which can vary depending on pixel voltage, e.g., depending on the image to be displayed. Gate line 711 can be shared with the display pixels of the sense region, therefore the signal may be leaked into the display pixels of the sense region through a similar mechanism shown in the figure. In particular, the signal can pass into sense pixel electrode 807 through a gate-to-drain capacitance CGDsense 809 of the TFTs in the display pixels of the sense region. The signal can then be passed from pixel electrode 807 to sense region Vcom 703 through the liquid crystal 719 of the sense region display pixels, the liquid crystal having an associated capacitance CLCsense 811. In other words, the signal can be transmitted through an electrical pathway including drive pixel electrode 705, the capacitive coupling CGDdrive 805 of a pixel TFT, gate line 711, the capacitive coupling CGDsense 809 of another pixel TFT, and sense pixel electrode 807. The leaked signal can show up in the touch measurements detected by sense amplifier 813.

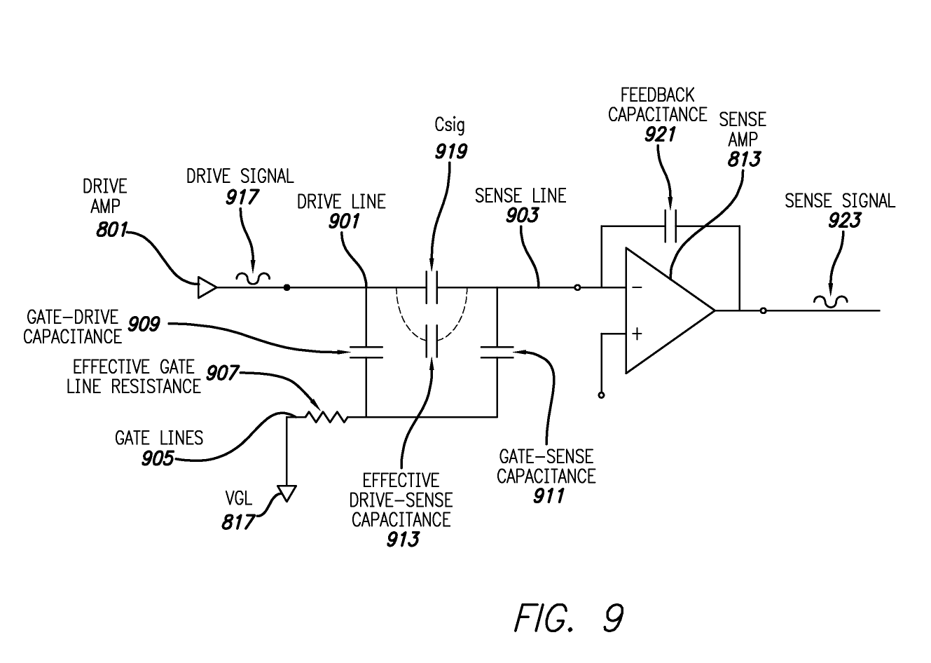

FIG. 9 illustrates an example circuit diagram of the example touch screen configuration 700 shown in FIG. 7. FIG. 9 includes the example error mechanism 800 of FIG. 8. In the previous examples of FIGS. 7 and 8, for the sake of clarity, only one drive Vcom/sense Vcom pair were described. However, as shown in the example embodiments described in FIGS. 4 through 6, the drive lines and sense lines of an integrated touch screen can include the Vcoms of multiple display pixels grouped together in a region of the touch screen. In the example circuit diagram of FIG. 9, a drive line 901 can include drive region segments such as drive region segment 403 linked together with bypasses as described in FIGS. 3 and 5, and a sense line 903 can include a sense region such as sense region 405 including a sense region such as sense region 405, including electrically connected together Vcoms of display pixels in the sense region as described in the figures. Gate lines 905 can include multiple gate lines such as gate lines 711 running through multiple rows of display pixels in the drive line 901 and portion of the sense line 903. For example, there may be 60 gate lines 905 in each drive line 901. An effective gate line resistance 907 can include a combination of resistances associated with the multiple gate lines 905, such as gate line resistance 819, TFT resistance 821, and routing resistance 823 of each of the 60 gate lines, for example. Likewise, a gate-drive capacitance 909 can include a combination of various capacitances between the multiple drive Vcom 701 and each corresponding gate line 905. For example, gate-drive capacitance 909 can include a combination of the CLCdrive 803 and CGDdrive 805 of each display pixel in the drive region. Likewise, a gate-sense capacitance 911 can include a combination of the CLCsense 811 and CGDsense 809 of all of the display pixels in the sense region. Effective drive-sense capacitance 913 can, therefore, represent the total effective capacitance between the drive and sense regions due to the various capacitances associated with each of the display pixels in the regions.

Drive amplifier 801 can generate a drive signal 917 on drive line 901 that can emanate from the multiple drive Vcoms in the drive region. The signal emanating from the drive Vcoms can be received through a touch-sensing mechanism to generate a signal capacitance, CSIG 919. The touch-sensing mechanism can include sense line 903 and sense amplifier 813a, with feedback capacitance 921, that can amplify the received signal to result in a sense signal 923 representing touch information received by the sense line. The signal emanating from the drive Vcoms can also be received by sense line 903 through the various error mechanisms of error mechanism 800, which can result in an error represented by effective drive-sense capacitance 913. In other words, a portion of the drive signal can reach sense line 903 through various error mechanisms. Therefore, sense signal 923 can be a superposition of multiple CSIG signals 919, which can carry touch information, together with multiple signals due to error mechanism 800. For example, errors caused by variations in the gate-to-drain capacitances of the pixel TFTs could be introduced into the touch-sensing mechanism through error mechanism 800.

FIGS. 10-17 illustrate example touch screen display pixel TFTs, such as pixel TFT 707, including semiconductive channels with doping profiles according to various embodiments. FIGS. 10-13 are cross-section views of example pixel TFTs. FIGS. 14-17 are plan views of example pixel TFTs. FIGS. 10-17 illustrate various doping profiles of semiconductive channels according to various embodiments. FIGS. 10, 11, 14, and 15 illustrate example semiconductive channels having asymmetric doping profiles. FIGS. 12, 13, 16, and 17 illustrate example semiconductive channels having symmetric doping profiles.

FIG. 10 illustrates an example pixel TFT 1000 that includes a source 1001, a drain 1003, a gate 1005, a gate 1007, a gate insulation layer 1009, a semiconductive channel 1011, a substrate 1013, and a dielectric layer 1015. Source 1001 can be connected to a data line (not shown), such as data line 723, and drain 1003 can be connected to a pixel electrode (not shown), such as 705. Semiconductive channel 1011 includes regions doped at different levels of concentration, including a heavily doped region (HDR) 1017 below source 1001, a lightly doped region (LDR) 1019 between source 1001 and gate 1005, an intrinsic region 1021 below gate 1005, an LDR 1023, an HDR 1025, and an LDR 1027 between gate 1005 and gate 1007, and an intrinsic region 1029 below gate 1007. An HDR 1031 extends between gate 1007 and drain 1003.

In other words, semiconductive channel 1011 can include a dopant profile along the length of the channel. The dopant profile can include a heavily doped region between the drain and a gate, such as the gate nearest to the drain. This heavily doped region can prevent or reduce variation in the gate-to-drain capacitance due to variation in drain voltage, e.g., pixel electrode voltage.

FIG. 11 illustrates an example pixel TFT 1100 that includes a source 1101, a drain 1103, a gate 1105, a gate 1107, a gate insulation layer 1109, a semiconductive channel 1111, a substrate 1113, and a dielectric layer 1115. Source 1101 can be connected to a data line (not shown), such as data line 723, and drain 1103 can be connected to a pixel electrode (not shown), such as 705. Semiconductive channel 1111 includes regions doped at different levels of concentration, including an HDR 1117 below source 1101, an LDR 1119 between source 1101 and gate 1105, an intrinsic region 1121 below gate 1105, an LDR 1123 between gate 1105 and gate 1107, and an intrinsic region 1125 below gate 1107. An HDR 1127 extends between gate 1107 and drain 1103.

FIG. 12 illustrates an example pixel TFT 1200 that includes a source 1201, a drain 1203, a gate 1205, a gate 1207, a gate insulation layer 1209, a semiconductive channel 1211, a substrate 1213, and a dielectric layer 1215. Source 1201 can be connected to a data line (not shown), such as data line 723, and drain 1203 can be connected to a pixel electrode (not shown), such as 705. Semiconductive channel 1211 includes regions doped at different levels of concentration, including an HDR 1217 extending from below source 1201 to gate 1205, an intrinsic region 1219 below gate 1205, an LDR 1221, an HDR 1223, and an LDR 1225 between gate 1205 and gate 1207, and an intrinsic region 1227 below gate 1207. An HDR 1229 extends between gate 1207 and drain 1203.

FIG. 13 illustrates an example pixel TFT 1300 that includes a source 1301, a drain 1303, a gate 1305, a gate 1307, a gate insulation layer 1309, a semiconductive channel 1311, a substrate 1313, and a dielectric layer 1315. Source 1301 can be connected to a data line (not shown), such as data line 723, and drain 1303 can be connected to a pixel electrode (not shown), such as 705. Semiconductive channel 1311 includes regions doped at different levels of concentration, including an HDR 1317 extending from below source 1301 to gate 1305, an intrinsic region 1319 below gate 1305, an LDR 1321 between gate 1305 and gate 1307, and an intrinsic region 1323 below gate 1307. An HDR 1325 extends between gate 1307 and drain 1303.

FIG. 14 is a plan view illustrating a portion of an example touch screen display sub-pixel 1400 according to various embodiments. An example structure of a pixel TFT is shown, including a source 1401, a drain 1403, a gate 1405, and a gate 1407. A semiconductive channel of the pixel TFT can include an LDR 1409 between source 1401 and gate 1405, an LDR 1411, an HDR 1413, and an LDR 1415 between gate 1405 and gate 1407, and an HDR 1417 between gate 1407 and drain 1403. The dopant profile of the semiconductive channel in FIG. 14 can be similar to the dopant profile of semiconductive channel 1011 of FIG. 10, for example.

A data line 1419 can be connected to source 1401, and a gate line 1421 can be connected to gate 1405 and gate 1407. Drain 1403 can be connected to a pixel electrode 1423 of the touch screen. Touch screen display sub-pixel 1400 can include a portion of a touch-sensing drive line 1425, for example, a common electrode (Vcom), that can be stimulated with a drive signal during a touch sensing phase.

FIG. 15 is a plan view illustrating a portion of an example touch screen display pixel 1500 according to various embodiments. An example structure of a pixel TFT is shown, including a source 1501, a drain 1503, a gate 1505, and a gate 1507. A semiconductive channel of the pixel TFT can include an LDR 1509 between source 1501 and gate 1505, an LDR 1511 between gate 1505 and gate 1507, and an HDR 1513 between gate 1507 and drain 1503. The dopant profile of the semiconductive channel in FIG. 15 can be similar to the dopant profile of semiconductive channel 1111 of FIG. 11, for example.

A data line 1515 can be connected to source 1501, and a gate line 1517 can be connected to gate 1505 and gate 1507. Drain 1503 can be connected to a pixel electrode 1519 of the touch screen. Touch screen display sub-pixel 1500 can include a portion of a touch-sensing drive line 1521, for example, a common electrode (Vcom), that can be stimulated with a drive signal during a touch sensing phase.

FIG. 16 is a plan view illustrating a portion of an example touch screen display pixel 1600 according to various embodiments. An example structure of a pixel TFT is shown, including a source 1601, a drain 1603, a gate 1605, and a gate 1607. A semiconductive channel of the pixel TFT can include an HDR 1609 between source 1601 and gate 1605, an LDR 1611, an HDR 1613, and an LDR 1615 between gate 1605 and gate 1607, and an HDR 1617 between gate 1607 and drain 1603. The dopant profile of the semiconductive channel in FIG. 16 can be similar to the dopant profile of semiconductive channel 1211 of FIG. 12, for example.

A data line 1619 can be connected to source 1601, and a gate line 1621 can be connected to gate 1605 and gate 1607. Drain 1603 can be connected to a pixel electrode 1623 of the touch screen. Touch screen display sub-pixel 1600 can include a portion of a touch-sensing drive line 1625, for example, a common electrode (Vcom), that can be stimulated with a drive signal during a touch sensing phase.

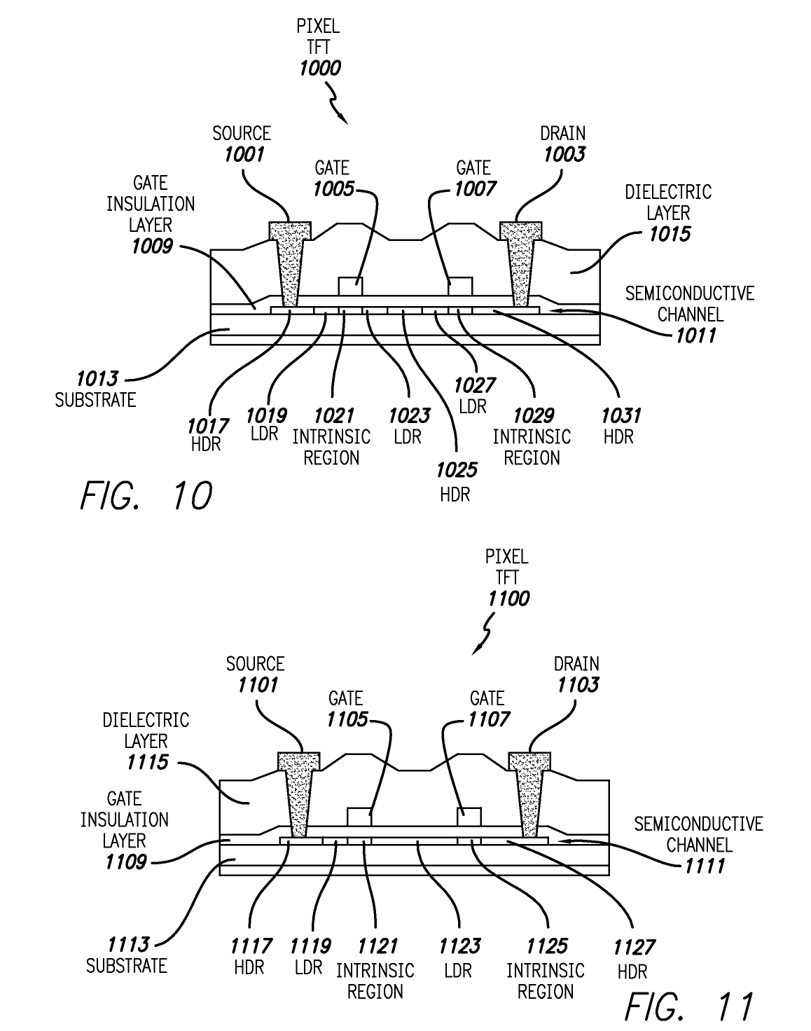

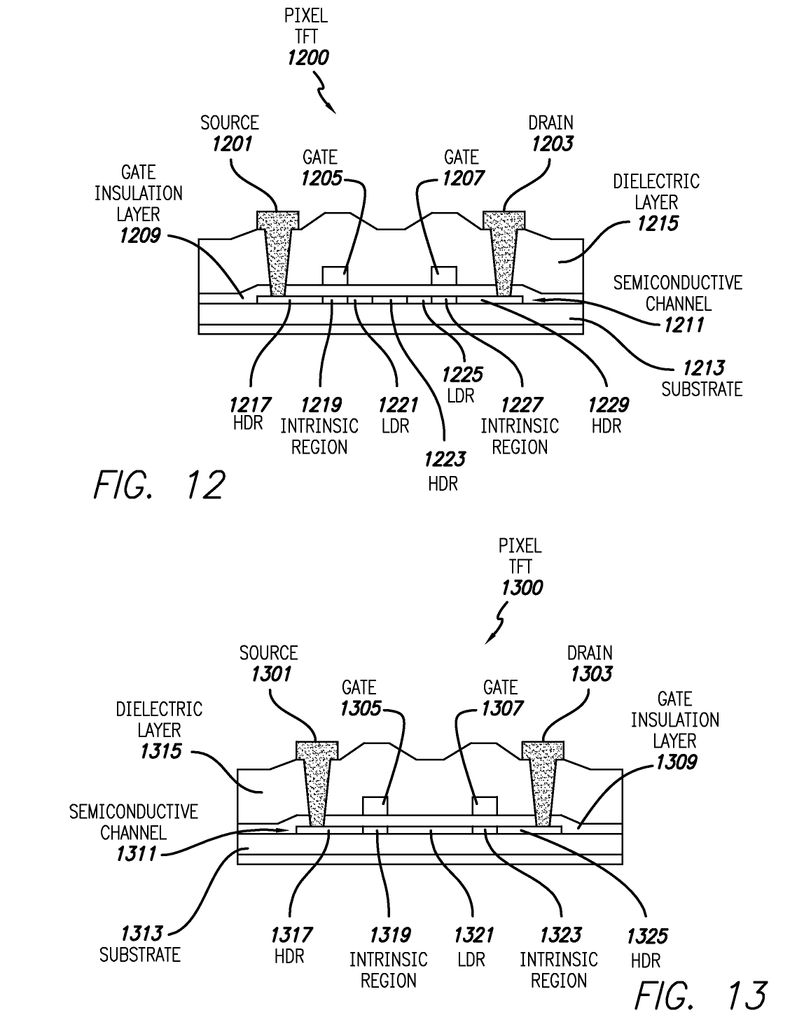

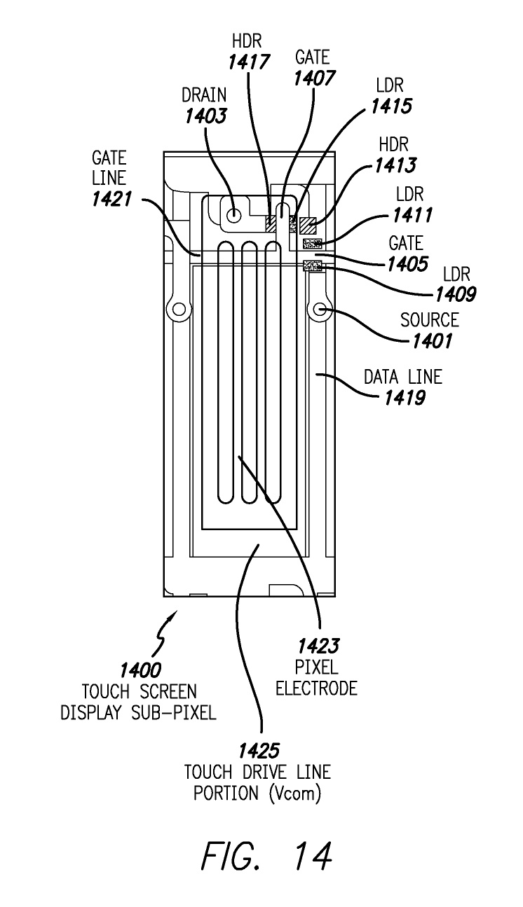

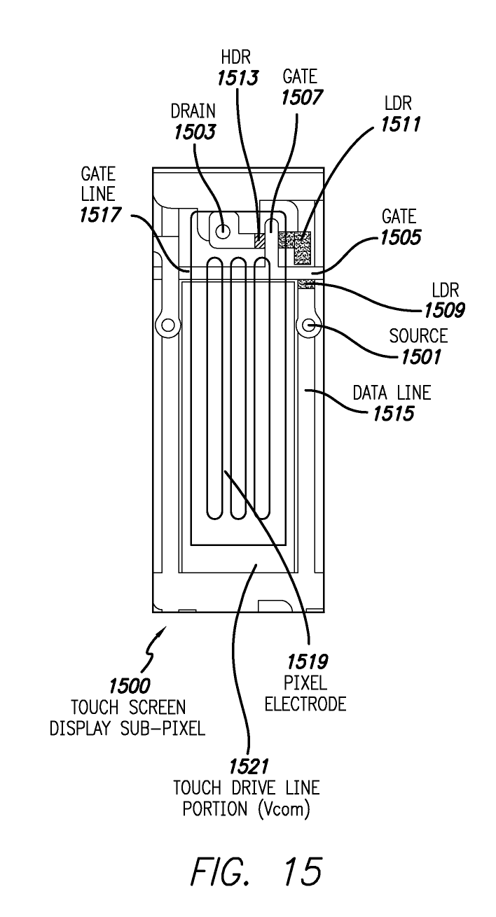

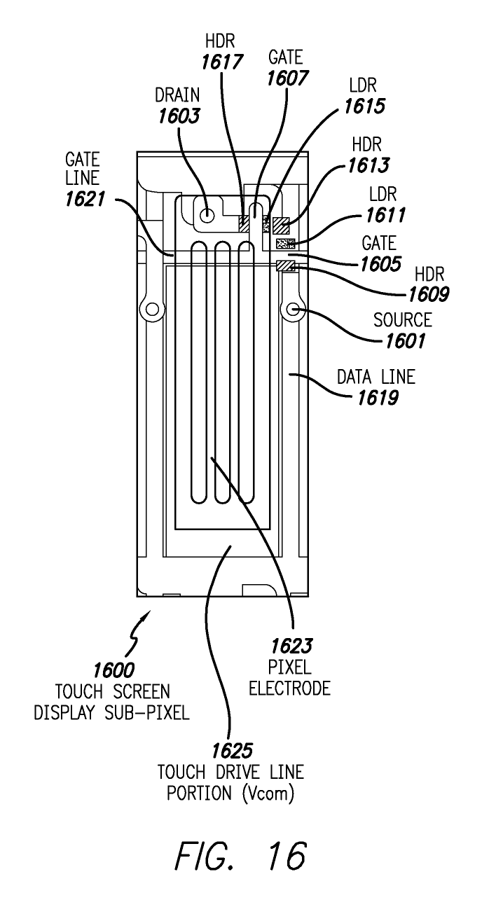

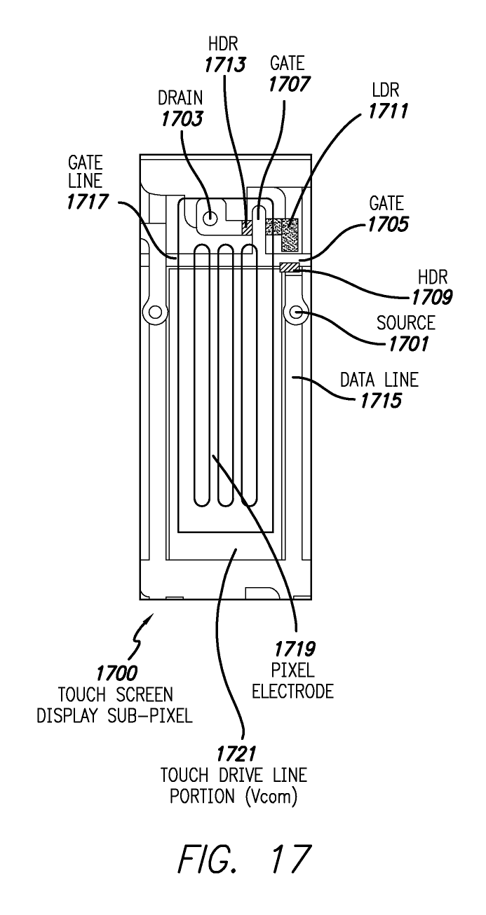

FIG. 17 is a plan view illustrating a portion of an example touch screen display pixel 1700 according to various embodiments. An example structure of a pixel TFT is shown, including a source 1701, a drain 1703, a gate 1705, and a gate 1707. A semiconductive channel of the pixel TFT can include an HDR 1709 between source 1701 and gate 1705, an LDR 1711 between gate 1705 and gate 1707, and an HDR 1713 between gate 1707 and drain 1703. The dopant profile of the semiconductive channel in FIG. 17 can be similar to the dopant profile of semiconductive channel 1311 of FIG. 13, for example.

A data line 1715 can be connected to source 1701, and a gate line 1717 can be connected to gate 1705 and gate 1707. Drain 1703 can be connected to a pixel electrode 1719 of the touch screen. Touch screen display sub-pixel 1700 can include a portion of a touch-sensing drive line 1721, for example, a common electrode (Vcom), that can be stimulated with a drive signal during a touch sensing phase.

In some embodiments, a semiconductive channel can be doped with a single dopant in different concentrations in different regions of the channel, such that the dopant profile can be a profile of dopant concentration. In some embodiments, different regions of a semiconductive channel can be doped with different dopants, such that the dopant profile can be a profile of dopant materials. One skilled in the art would understand that a combination of dopant materials and concentrations can be used. In addition, although example embodiments are described using dual-gate TFTs, one skilled in the art would understand in light of the disclosed examples how dopant profiles can be formed in semiconductive channels of transistors of other structures or types, such as single-gate TFTs.

Although embodiments of this disclosure have been fully described with reference to the accompanying drawings, it is to be noted that various changes and modifications including, but not limited to, combining features of different embodiments, omitting a feature or features, etc., as will be apparent to those skilled in the art in light of the present description and figures.

Example embodiments may be described herein with reference to a Cartesian coordinate system in which the x-direction and the y-direction can be equated to the horizontal direction and the vertical direction, respectively. However, one skilled in the art will understand that reference to a particular coordinate system is simply for the purpose of clarity, and does not limit the direction of the elements to a particular direction or a particular coordinate system. Furthermore, although specific materials and types of materials may be included in the descriptions of example embodiments, one skilled in the art will understand that other materials that achieve the same function can be used. For example, it should be understood that a “metal layer” as described in the examples below can be a layer of any electrically conductive material.

In some embodiments, the drive lines and/or sense lines can be formed of other elements including, for example other elements already existing in typical LCD displays (e.g., other electrodes, conductive and/or semiconductive layers, metal lines that would also function as circuit elements in a typical LCD display, for example, carry signals, store voltages, etc.), other elements formed in an LCD stackup that are not typical LCD stackup elements (e.g., other metal lines, plates, whose function would be substantially for the touch sensing system of the touch screen), and elements formed outside of the LCD stackup (e.g., such as external substantially transparent conductive plates, wires, and other elements). For example, part of the touch sensing system can include elements similar to known touch panel overlays.

In the example embodiments, each sub-pixel can be a red (R), green (G), or blue (B) sub-pixel, with the combination of all three R, G and B sub-pixels forming one color display pixel. One skilled in the art would understand that other types of touch screen could be used. For example, in some embodiments, a sub-pixel may be based on other colors of light or other wavelengths of electromagnetic radiation (e.g., infrared) or may be based on a monochromatic configuration, in which each structure shown in the figures as a sub-pixel can be a pixel of a single color.

What is claimed is:

1. A touch screen comprising:
a drive line that carries a stimulation signal during a touch sensing phase;
a sense line that receives a sense signal during the touch sensing phase, the sense signal being based on the stimulation signal;
a display circuit element that maintains a voltage during the touch sensing phase;
a voltage supply system that supplies the voltage to the display circuit element during a display phase;
a transistor with a drain connected to the display circuit element and a source connected to the voltage supply system, the transistor including one or more gates, at least one gate being a gate closest to the drain, and a semiconductive channel including a first region of a first concentration of dopant, the first region disposed between the drain and the gate closest to the drain, and a second region of a second concentration of dopant, the second region disposed between the source and the gate closest to the drain, wherein the first concentration of dopant is greater than the second concentration of dopant; and
a control system that, during the display phase, switches the transistor to an on state, controls the voltage supply system to supply the voltage to the display circuit element during the on state of the transistor, and switches the transistor to an off state after the display circuit element is supplied with the voltage and prior to the touch sensing phase, such that the transistor is held in the off state during touch sensing.

2. The touch screen of claim 1, wherein the display circuit element includes a pixel electrode.

3. The touch screen of claim 1, wherein the transistor includes a thin film transistor.

4. The touch screen of claim 1, wherein the first region extends from the drain to the gate closest to the drain.

5. The touch screen of claim 1, wherein the semiconductive channel further includes a third region of the first concentration of dopant, the third region disposed between the source and the gate closest to the drain.

6. The touch screen of claim 5, wherein the third region is disposed between the second region and the source.

7. The touch screen of claim 6, wherein a dopant concentration profile of the semiconductive channel includes the first, second, and third regions, and the dopant concentration profile is symmetrical about a midpoint along the length of the semiconductive channel.

8. The touch screen of claim 1, wherein a dopant concentration profile of the semiconductive channel includes the first and second regions, and the dopant concentration profile is asymmetrical about a midpoint along the length of the semiconductive channel.

9. A touch screen system comprising:
an integrated touch sensing system including a drive portion that generates stimulation signals and applies the stimulation signals to a plurality of first circuit elements within display pixel stackups of a touch screen panel, and a sense portion including second circuit elements within the display pixel stackups, the second circuit elements receiving first signals based on the stimulation signals, the first signal being sense signals;
a plurality of third circuit elements within the display pixel stackups, the third circuit elements receiving second signals based on the stimulation signals;
a plurality of transistors, each transistor including one or more gates, a drain connected to one of the third circuit elements, and a semiconductive channel including a first region of a first concentration of dopant, the first region disposed between the drain and a gate closest to the drain, and a second region of a second concentration of dopant, the second region disposed between a source of the transistor and the gate closest to the drain, wherein the first concentration of dopant is greater than the second concentration of dopant; and
an electrical pathway connecting one of the third circuit elements to one of the second circuit elements, the electrical pathway including a gate-to-drain capacitance of the transistor connected to the third circuit element, wherein the second signal is coupled to the second circuit element through the electrical pathway.

10. The touch screen system of claim 9, wherein the electrical pathway further includes a gate-to-drain capacitance of another of the plurality of transistors.

11. The touch screen system of claim 9, wherein the third circuit elements include pixel electrodes.

12. The touch screen system of claim 9, wherein the electrical pathway further includes a gate line of the touch screen.

13. The touch screen system of claim 9, wherein the first region extends from the drain to the gate closest to the drain.

14. The touch screen system of claim 9, wherein the semiconductive channel further includes a third region of the first concentration of dopant, the third region disposed between the source and the gate closest to the drain.

15. The touch screen system of claim 14, wherein the third region is disposed between the second region and the source.

16. The touch screen system of claim 14, wherein a dopant concentration profile of the semiconductive channel includes the first, second, and third regions, and the dopant concentration profile is symmetrical about a midpoint along the length of the semiconductive channel.

17. The touch screen system of claim 9, wherein a dopant concentration profile of the semiconductive channel includes the first and second regions, and the dopant concentration profile is asymmetrical about a midpoint along the length of the semiconductive channel.

18. The touch screen system of claim 9, further comprising a voltage supply system that supplies a voltage to the plurality of third circuit elements during a display phase of the touch screen.

19. The touch screen system of claim 18, wherein the voltage supply system is connected to the sources of the transistors, and the voltage is supplied to the third circuit elements during an on state of the corresponding transistors.

20. A computer system comprising:
a processor;
a memory; and
an integrated touch screen including
a drive line that carries a stimulation signal during a touch sensing phase,
a sense line that receives a sense signal during the touch sensing phase, the sense signal being based on the stimulation signal,
a display circuit element that maintains a voltage during the touch sensing phase,
a voltage supply system that supplies the voltage to the display circuit element during a display phase,
a transistor with a drain connected to the display circuit element and a source connected to the voltage supply system, the transistor including one or more gates, at least one gate being a gate closest to the drain, and a semiconductive channel including a first region of a first concentration of dopant, the first region disposed between the drain and the gate closest to the drain, and a second region of a second concentration of dopant, the second region disposed between the source and the gate closest to the drain, wherein the first concentration of dopant is greater than the second concentration of dopant, and
a control system that, during the display phase, switches the transistor to an on state, controls the voltage supply system to supply the voltage to the display circuit element during the on state of the transistor, and switches the transistor to an off state after the display circuit element is supplied with the voltage and prior to the touch sensing phase, such that the transistor is held in the off state during touch sensing.

21. A method of manufacturing an integrated touch screen, the method comprising:
forming plurality of display pixel stackups including
a plurality of drive lines,
a plurality of sense lines,
a plurality of gate lines,
a plurality of data lines,
a plurality of pixel electrodes, and
a plurality of transistors, each transistor including a drain connected to one of the pixel electrodes and a source connected to one of the data lines, the transistor including one or more gates connected to one of the gate lines, at least one gate being a gate closest to the drain, and a semiconductive channel including a first region of a first concentration of dopant, the first region disposed between the drain and the gate closest to the drain, and a second region of a second concentration of dopant, the second region disposed between the source and the gate closest to the drain, wherein the first concentration of dopant is greater than the second concentration of dopant.

22. The method of claim 21, wherein the first region extends from the drain to the gate closest to the drain.

23. The method of claim 21, wherein the semiconductive channel further includes a third region of the first concentration of dopant, the third region disposed between the source and the gate closest to the drain.

24. The method of claim 23, wherein the third region is disposed between the second region and the source.

25. The method of claim 24, wherein a dopant concentration profile of the semiconductive channel includes the first, second, and third regions, and the dopant concentration profile is symmetrical about a midpoint along the length of the semiconductive channel.

26. The method of claim 21, wherein a dopant concentration profile of the semiconductive channel includes the first and second regions, and the dopant concentration profile is asymmetrical about a midpoint along the length of the semiconductive channel.
